(19) United States
(12) Patent Application Publication
(10) Pub. No.: US 2023/0290684 A1
(43) Pub. Date: Sep. 14, 2023

(54) STRUCTURES AND METHODS FOR DICING SEMICONDUCTOR DEVICES

(71) Applicant: Micron Technology, Inc., Boise, ID (US)

(72) Inventors: Wei Chang Wong, Singapore (SG); Radhakrishna Kotti, Meridian, ID (US); Raj K. Bansal, Boise, ID (US); Youngik Kwon, Taichung (TW); Po Chih Yang, Taichung (TW); Venkateswarlu Bhavanasi, Singapore (SG)

(21) Appl. No.: 17/690,981

(22) Filed: Mar. 9, 2022

(51) Int. Cl. H01L 21/78; H01L 23/58

(52) U.S. Cl. CPC H01L 21/78; H01L 23/585; H01L 27/108

(57) ABSTRACT

Structures and methods for separating semiconductor wafers into individual dies are disclosed. A semiconductor wafer or panel can include a crack assist structure in a scribe junction. The crack assist structure can include a plurality of vertical walls extending at least partially through a thickness of the wafer. In some embodiments, the plurality of vertical walls can be coupled to a weak interface. The weak interface can guide cracks that form during the dicing process in a direction along the walls, away from active circuitry. After dicing, the resulting semiconductor devices can include a plurality of vertical walls extending at least partially through a thickness of the semiconductor device. Each of the plurality of vertical walls can include at least a portion extending substantially parallel to a sidewall of the semiconductor device.

### TECHNICAL FIELD

The present disclosure generally relates to structures and methods for separating semiconductor wafers into individual dies.

### BACKGROUND

Semiconductor device assemblies are generally fabricated with multiple semiconductor devices on a single silicon wafer. These semiconductor wafers are then separated into individual semiconductor dies through a dicing process. There are a number of processes used to separate a semiconductor wafer into individual semiconductor dies. For example, the semiconductor wafer can be cut with a mechanical saw. Other processes include stealth dicing and stealth dicing before grinding (“SDBG”), which use a controlled fracturing process to separate the wafer into dies. In each of these processes, there is a risk that cracks can form along the edges and corners of the dies and propagate toward the active components of the dies, damaging the components and decreasing die yield. Thus, mechanisms are needed to address these cracks.

### BRIEF DESCRIPTION OF THE DRAWINGS

Many aspects of the present technology can be better understood with reference to the following drawings. The components in the drawings are not necessarily to scale. Instead, emphasis is placed on illustrating clearly the principles of the present technology.

FIG. 1 is a top view of an intermediate semiconductor device including a crack assist structure in accordance with embodiments of the present disclosure.

FIG. 2 is a cross-sectional view of a semiconductor wafer 200 including a crack assist structure 210 in accordance with embodiments of the present disclosure.

FIG. 3 is a top view of an intermediate semiconductor device including a crack assist structure in accordance with embodiments of the present disclosure.

FIG. 4 is a top view of an intermediate semiconductor device including a crack assist structure in accordance with embodiments of the present disclosure.

FIG. 5 is a top view of a semiconductor device 500 in accordance with an embodiment of the present disclosure.

FIG. 6 is a flow chart illustrating a method of forming a semiconductor device including a crack assist structure in accordance with an embodiment of the present disclosure.

FIG. 7 is a cross-sectional view of semiconductor device assembly undergoing stealth dicing in accordance with an embodiment of the present disclosure.

FIG. 8 shows a laser performing stealth dicing on a semiconductor wafer in accordance with an embodiment of the present disclosure.

FIG. 9 is a schematic view of a system that includes a semiconductor device assembly configured in accordance with embodiments of the present technology.

### DETAILED DESCRIPTION

In this disclosure, numerous specific details are discussed to provide a thorough and enabling description for embodiments of the present disclosure. One of ordinary skill in the art will recognize that the disclosure can be practiced without one or more of the specific details. Well-known structures and/or operations often associated with semiconductor devices may not be shown and/or may not be described in detail to avoid obscuring other aspects of the disclosure. In general, it should be understood that various other devices, systems, and/or methods in addition to those specific embodiments disclosed herein may be within the scope of the present disclosure.

The term “semiconductor device assembly” can refer to an assembly of one or more semiconductor devices, semiconductor device packages, and/or substrates, which may include interposers, supports, and/or other suitable substrates. The semiconductor device assembly may be manufactured as, but not limited to, discrete package form, strip or matrix form, and/or wafer panel form. The term “semiconductor device” generally refers to a solid-state device that includes semiconductor material. A semiconductor device can include, for example, a semiconductor substrate, wafer, panel, or a single die from a wafer or substrate. A semiconductor device may further include one or more device layers deposited on a substrate. A semiconductor device may refer herein to a semiconductor die, but semiconductor devices are not limited to semiconductor dies.

Semiconductor dies are generally organized in a rectilinear array of rows and columns that are separated by streets, also referred to as “saw streets,” “saw lanes”, “scribe lines,” “kerf regions,” and various other terms. The use of any of these terms does not imply use of a particular singulation method. For example, the term “saw street” can be used with reference to singulation by any mechanism, including a mechanical saw, laser cutting, stealth dicing, scribing, etc.

Stealth dicing before grinding (“SDBG”) is a dicing process that is increasingly popular among semiconductor device manufacturers. SDBG uses a controlled fracturing process to separate the semiconductor dies. In SDBG, a laser is used to introduce defect regions in an applied pattern within the silicon wafer, referred to as “stealth dicing”. The wafer is then thinned by grinding. Finally, mechanical stress is applied to the wafer, which then causes the wafer to preferentially fracture though the defect regions in the applied pattern, thereby separating the wafer into individual dies. Compared to dicing with a saw, SDBG can result in less debris and cause less thermomechanical stress to the wafer. In addition, stealth dicing is a dry process that does not require a cooling liquid. Dicing before grinding (“DBG”) is a similar process that uses a saw to cut the wafer at a partial depth instead of stealth dicing with a laser.

Because SDBG purposely introduces fractures in the semiconductor wafer, there is a risk these fractures may deviate from the applied pattern and propagate as cracks toward the active components of the semiconductor devices, damaging the components. Crystals such as silicon often cleave in directions corresponding to their lattice structure, making the risk of cracks especially high when the wafer is diced at an angle that diverges from these cleavage directions. For example, a CMOS device fabricated on a 45-degree silicon wafer may exhibit improved carrier mobility compared to traditional orientations. But when the wafer is diced or stealth diced at a 45-degree angle relative to the direction of the lattice, cracks can easily form, especially at the corners of the die.

Embodiments of the present disclosure address the foregoing challenges and others by providing and methods that can be used to prevent cracks from propagating to the active components of a semiconductor die during the dicing process. A crack assist structure can be formed in a scribe junction of a semiconductor wafer. The crack assist structure can be comprised of a plurality of walls that include a portion running substantially parallel to a die region of the semiconductor die containing the active components. These walls can be coupled to a weak interface region that provides a path of least resistance for cracks to travel through. Thus, when a crack propagates toward the crack assist structure, the crack can propagate through the weak interface toward the parallel portion of the wall, where it's guided away from the active components in the die region. In some embodiments, the weak interface can include an air gap. In addition to protecting active components of the dies and improving yield, the embodiments described herein can improve dicing quality and reduce chipping at edges and corners.

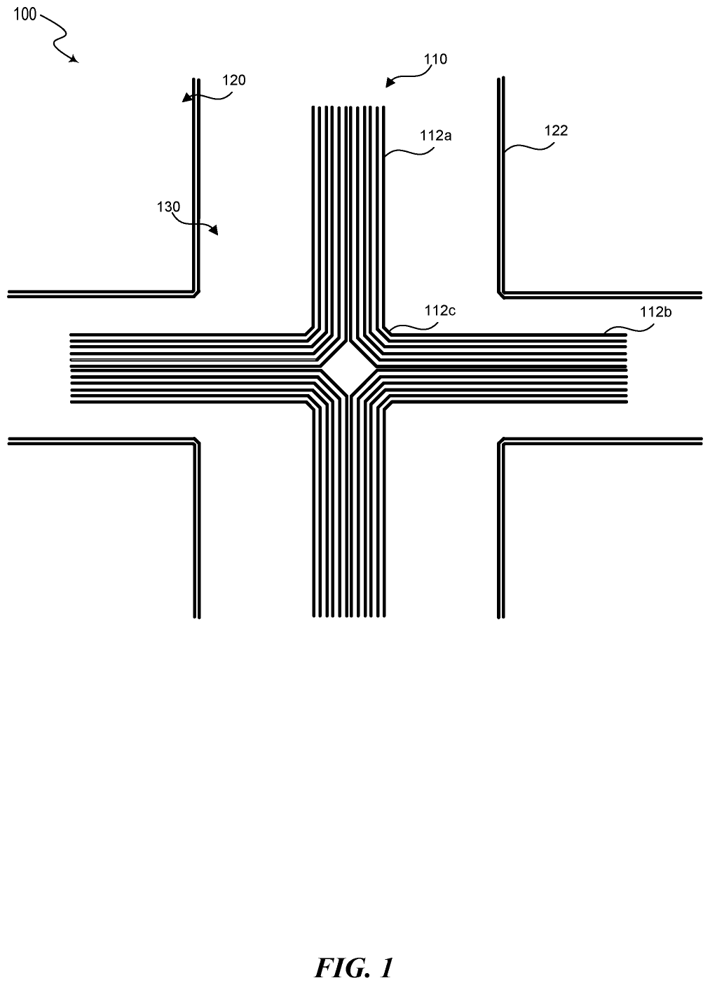

FIG. 1 is a top view of an intermediate semiconductor device 100 including a crack assist structure 110 in accordance with embodiments of the present disclosure. The intermediate semiconductor device 100 can be a wafer or a panel that has not yet been separated into individual strips or dies. The intermediate semiconductor device 100 can include a plurality of die regions 120 corresponding to the individual dies. For example, FIG. 1 shows four die regions 120 proximate to one another in a rectilinear arrangement. The die regions 120 can include active components of the individual dies such as integrated circuitry. The semiconductor device can also include a scribe line region 130 along the periphery of the die regions 120. The scribe line region 130 can include scribe lines running parallel to the edges of the die regions 120, such as a first scribe line running in a first direction and a second scribe line running in a second direction orthogonal to the first direction. The intermediate semiconductor device 100 can be cut, scribed, or otherwise separated along the scribe lines to produce individual strips or dies.

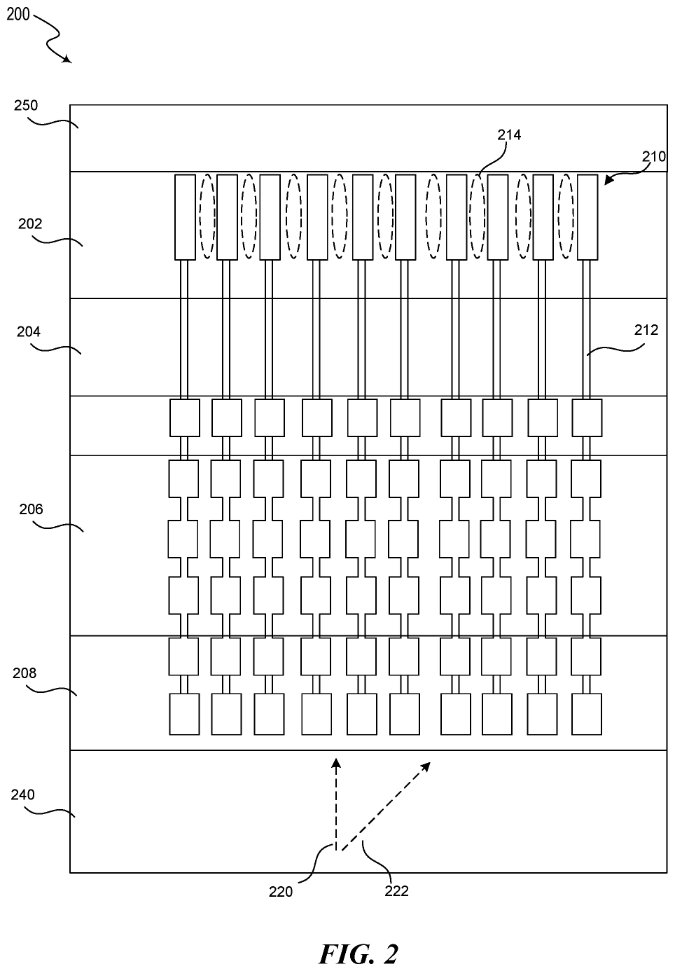

The scribe line region 130 can include a crack assist structure 110 configured to guide cracks away from the die region 120. For example, FIG. 1 shows a crack assist structure positioned centrally in the scribe line region 130 between four proximate die regions 120. The crack assist structure 110 can comprise multiple walls 112. The walls 112 can be coupled to weak interface regions through which a crack is likely to propagate. For example, the weak interface can be an air gap or a weak metal/oxide interface. The weak interface is configured to be a path of least resistance that ensures a crack is likely to be guided toward the walls 112 rather than toward the die regions 120. The walls 112 can include a portion that runs parallel to an edge of the die region 120, so cracks that travel between the walls 112 do not reach the die region 120. The walls 112 can be comprised of a metal, such as tungsten or copper, and extend vertically into the intermediate semiconductor device 100. The spacing between each wall can be approximately 1 μm, though generally the crack assist structure 110 will function similarly for various widths and spacings between the walls 112. The structure of the walls will be described in more detail with reference to FIG. 2 below.

In some embodiments, the die region 120 can be surrounded by a seal ring 122. The seal ring 122 can extend into the intermediate semiconductor device 100 and protect the die region from moisture and contamination. The seal ring 122 can be comprised of tungsten or other metals. The crack assist structure 110 can be comprised of walls 112 that have the same structure and can be comprised of the same materials as the seal ring 122. This can streamline the production process because the crack assist structure 110 can be formed using the same processes and equipment used to form the seal ring 122.

The crack assist structure 110 can have various arrangements. The crack assist structure 110 shown in FIG. 1 includes a plurality of walls 112 which do not intersect. Each wall 112 can include a first portion 112a, a second portion 112b, and a third portion 112c. As shown, the first portion 112a runs in a first direction parallel to an edge of the die region 120. The second portion 112b runs in a second direction parallel to another edge of the die region 120. Semiconductor dies are often separated into squares or rectangles, and accordingly the first and second directions can be orthogonal. The third portion 112c joins the first portion 112a and the second portion 112b to form a chamfered corner shape. For example, the third portion 112c can run at a 45-degree angle relative to the first and second portions 112a and 112b. The chamfered corner can help mitigate cracks that may form in wafers of 45-degree silicon. For a 45-degree silicon wafer, dicing along the scribe lines of scribe line region 130 can cause cracks to form at the intersection of the scribe lines, which can form at roughly a 45-degree angle due to the orientation of the lattice. Cracks at the intersection of the scribe line can result in dies with chipped corners. The chamfered corner can guide such cracks toward the portions parallel to the edges of the die region 120, either the first portion 112a or second portion 112b. Note that the configuration shown in FIG. 1 is an illustrative example, and other configurations of the walls 112 can be formed to guide cracks that may form during the dicing process. Also, note that the number of walls 112 need not be limited to the number shown in FIG. 1.

FIG. 2 is a cross-sectional view of an intermediate semiconductor device 200 including a crack assist structure 210 in accordance with embodiments of the present disclosure. The intermediate semiconductor device 200 can be a wafer or a panel and be similar to intermediate semiconductor device 100 of FIG. 1. The crack assist structure 210 can be similar to the crack assist structure 110 shown in FIG. 1. The crack assist structure can comprise a plurality of walls 212 extending vertically into the intermediate semiconductor device 200. The walls 212 can be coupled to weak interface regions 214 for cracks to propagate through. Thus, cracks that form in the intermediate semiconductor device 200 during the dicing process can be guided vertically toward the walls 212. For example, the weak interface regions 214 can include an air gap.

The intermediate semiconductor device 200 can include a backend of line (BEOL) layer 202, a memory layer 204, a dielectric layer 206, and an active layer 208. During stealth dicing, a laser is applied into a silicon substrate layer 240. The memory layer 204 can include a NAND memory array or a DRAM array (spaced laterally apart from the saw streets in which the crack assist structure 210 is located). In some embodiments, the dielectric layer 206 and active layer 208 can include complementary metal-oxide-semiconductor (CMOS) elements of a memory device (spaced laterally apart from the saw streets in which the crack assist structure 210 is located). In some embodiments, the crack assist structure 210 can be included in different semiconductor device assemblies besides memory devices. Thus, the various layers 202-208 are shown for illustration, and the intermediate semiconductor device 200 need not be a memory device with a memory layer 204 or CMOS elements.

FIG. 2 illustrates the depth of the crack assist structure 210 relative to the various layers 202-208. As illustrated, various metal connections are used to create the walls 212, which span the multiple layers 202-208, and where the bottom of the walls 212 reside in the silicon substrate layer 240. However, the crack assist structure 210 can generally be positioned in the scribe lines of the intermediate semiconductor device 200, and in that case would be spaced laterally apart from any memory or active circuitry. The crack assist structure 210 can include a plurality of walls 212 that extend from a depth corresponding to the BEOL layer 202 to a depth corresponding to the active layer 208. Each wall 212 can be comprised of tungsten or other metal. The walls can be coupled to the weak interface regions 214, such as air gaps. As shown, the crack assist structure 210 does not extend into the oxide layer 250. During stealth dicing, a laser can cleave the lattice of the silicon substrate layer 240. Laser leakage or splash at scribe corners can cause cracks to form in the silicon substrate layer 240, which can propagate in a direction that deviates from the intended direction. As shown in FIG. 2, direction 220 is the intended direction to singulate dies, and direction 222 is a direction of breakage caused by a crack. When a crack propagating in direction 222 encounters a wall 212 in regions 208 or 206, then the crack is guided along the wall 212 towards the direction of the weak interface.

In some embodiments, the crack assist structure 210 can also be used to guide cracks formed as a result of blade dicing to the front side of the intermediate semiconductor device 200. For example, blade dicing is generally performed with a diamond saw on the front side of a wafer, i.e., the active layer 208, or through packaging formed over the active layer 208. For blade dicing, crack assist structure 210 can be formed without the weak interface regions 214.

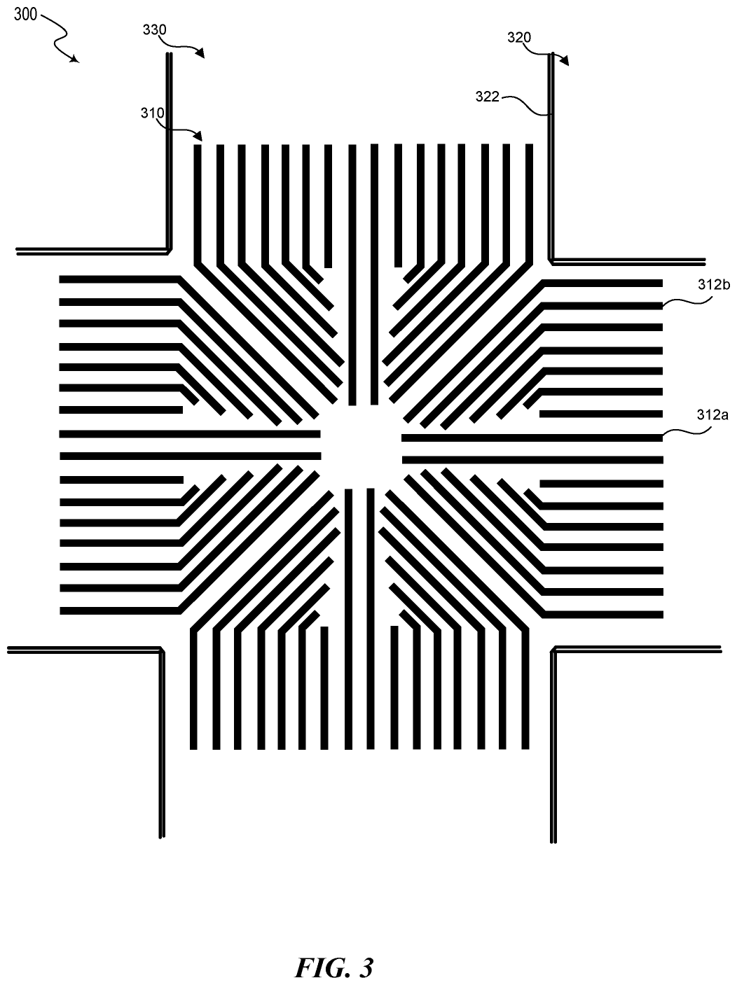

FIG. 3 is a top view of an intermediate semiconductor device 300 including a crack assist structure 310 in accordance with embodiments of the present disclosure. The intermediate semiconductor device 300 can include a plurality of die regions 320 similar to die regions 120 shown in FIG. 1. The crack assist structure 310 can include a plurality of walls similar to walls 112 of FIG. 1 and walls 212 of FIG. 2 but arranged in the design as shown. The walls can include a first set of walls 312 which run along the directions of the scribe lines of scribe line region 330. The walls can also include a second set of walls 314 that include a first portion 314a that runs in the direction of the scribe lines and a second portion 314b that runs at an angle relative to the first portion toward the first set of walls 312. For example, the second portion can be oriented 45-degrees relative to the first portion. The angled second portion 314b can guide cracks that form at an angle near the center of the scribe line region 330 toward the first portions 314a. This can be beneficial for wafers with a lattice that are not aligned with the scribe lines, such as 45-degree silicon. Furthermore, cracks that form near the first portion 314a can be guided along the second portion 314b toward the center of the scribe line region 330 away from the die regions 320. In addition, the angle between the first portion 314a and the second portion 314b can be any suitable angles between 0 and 90 degrees, such as 15 degrees, 30 degrees, 60 degrees, etc.

In some embodiments, the intermediate semiconductor device 300 can include seal rings 322, similar to seal rings 122 of FIG. 1. In some embodiments the seal rings 322 can be formed using the same material and processes used to form the crack assist structure 310. In some embodiments, the seal rings 322 can be formed using separate processes and materials.

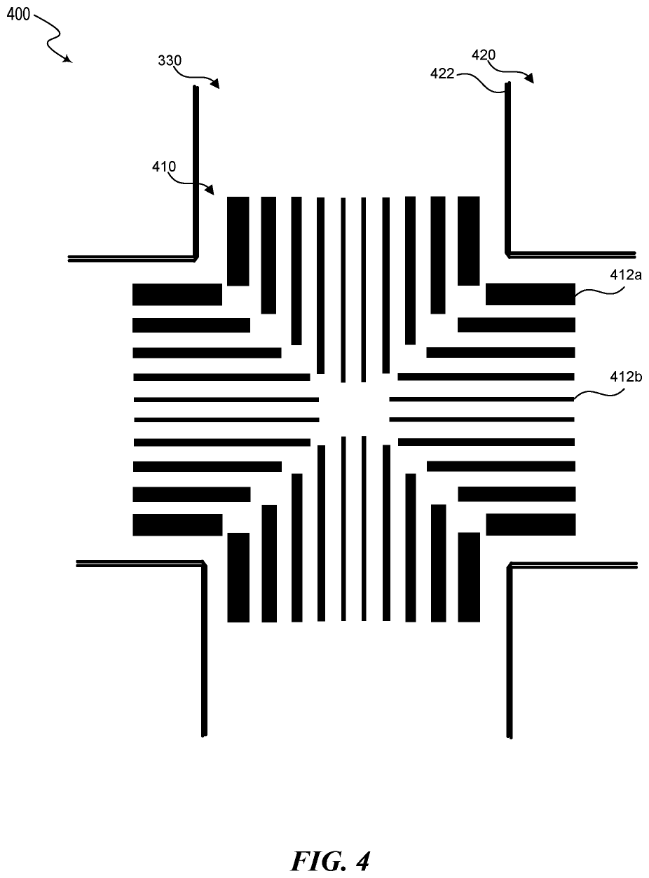

FIG. 4 is a top view of an intermediate semiconductor device 400 including a crack assist structure 410 in accordance with embodiments of the present disclosure. The intermediate semiconductor device 400 can include a plurality of die regions 420 similar to die regions 120 shown in FIG. 1 and die regions 320 of FIG. 3. The crack assist structure 410 can be positioned in the scribe line region 430 and include a plurality of walls 412 similar to walls 112 of FIG. 1, walls 212 of FIG. 2, and walls 312 and 314 of FIG. 3, but arranged in the design as shown.

The walls 412 can run in the directions of the scribe lines of scribe line region 430. The walls can vary in width based on a distance from the wall to the nearest die region 420. For example, wall 412a nearest a die region 420 can have a larger width than wall 412b nearer to a central axis. Additional walls closer to the central axis can be successively narrower. Thicker walls near the die region 420 can provide additional protection to the die regions 420 by because they are less likely to break and to allow cracks to propagate through them. Meanwhile, the walls nearer to a central axis of the scribe line region 430 can be thinner to reduce costs. The thickness of the walls 412 can vary in other ways, such as having wall 412a be narrower than wall 412b. In some embodiments, the thicknesses of the walls can vary arbitrarily. The arrangement of walls 412 can be symmetrical about both a horizontal axis and a vertical axis as shown. In addition, the walls 412 can be arranged such that none of the walls 412 intersect. In some embodiments, some of the walls 412 can intersect. For example, orthogonal walls can intersect to form a corner.

In some embodiments, the walls 412 can be segmented and include additional segments in different orientations. For example, the walls 412 can include angled segments similar to the walls 314 in FIG. 3 while also varying in width based on distance to the die regions 420. In addition, although FIG. 4 shows the walls 412 being narrower as distance from the die regions 420 increases, the walls 412 can vary in other ways. For example, it may be desired to alternate wide and narrow walls 412, or have narrower walls 412 nearer the die region 420.

In some embodiments, the intermediate semiconductor device 400 can include seal rings 422, similar to seal rings 122 of FIG. 1 and seal rings 322 of FIG. 2. In some embodiments, the seal rings 422 can be formed using the same material and processes used to form the crack assist structure 410. In some embodiments, the seal rings 422 can be formed using separate processes and materials.

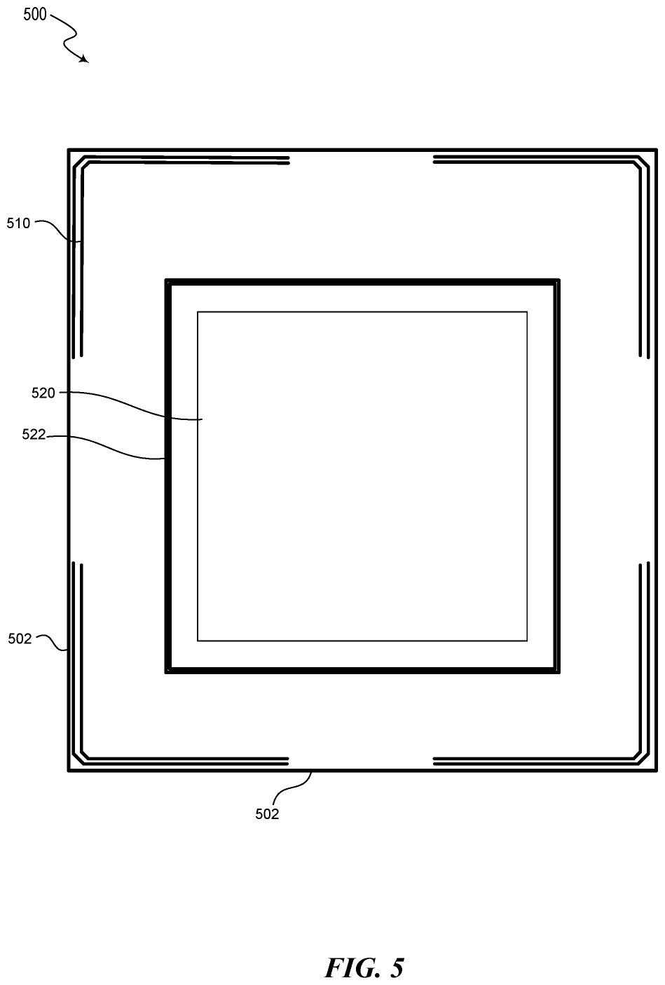

FIG. 5 is a top view of a semiconductor device 500 in accordance with an embodiment of the present disclosure. The semiconductor device can include a die region 520 surrounded by a seal ring 522. The die region 520 can include integrated circuitry and be similar to die regions 120, 320, or 420 of FIGS. 1, 2, and 4, respectively. The outer edges of the semiconductor device can be defined by a plurality of sidewalls 502. The semiconductor device 500 can be a rectangular shape, formed by dicing an intermediate semiconductor device, such as wafer or a panel. For example, the semiconductor device 500 can be an individual die produced by dicing the intermediate semiconductor device 100 of FIG. 1 along scribe lines in the scribe line region 130. The semiconductor device 500 can be singulated as a result of stealth dicing, stealth dicing before grinding, blade dicing, or other suitable dicing methods.

The semiconductor device 500 can include a plurality of walls 510. The walls 510 can prevent cracks that form during the dicing process from propagating toward the die region 520. For example, cracks may be present at the sidewalls 502 of the semiconductor device 500 but are prevented from propagating toward the die region 520 by the walls 510. The walls 510 can be comprised of metal and extend vertically into a depth of the semiconductor device 500. In some embodiments, the walls 510 can have a similar structure to the walls 212 of FIG. 2. For example, the walls 510 can be coupled to an air gap at a depth above a silicon substrate and extend upward to a depth corresponding to an active layer of the semiconductor device 500. In some embodiments, the walls 510 can be visible at the periphery of the semiconductor device 500 as viewed from above.

The walls 510 can be walls that were formerly part of a crack assist structure, such as crack assist structure 110. For example, dicing the intermediate semiconductor device 100 along the center of the scribe lines in scribe line region 130 can separate the four proximate die regions 120. As a result, the crack assist structure 110 can be split into at least four portions, each positioned near a corner of the respective die region 120. Therefore, the walls 510 positioned at each corner of the semiconductor device 500 can each be a remaining portion of a crack assist structure, respectively. In some embodiments, the walls 510 that remain after a dicing process can be similar to the walls 112, 212, 312, or 412, of the crack assist structures 110, 210, 310, or 410 shown in the previous figures.

For example, the walls 510 depicted in FIG. 5 can have a similar shape to the walls 112 of FIG. 1, including a chamfered corner as a result of dicing a wafer including crack assist structure 110. However, the walls 510 can have other shapes depending on the arrangement of the crack assist structure used in the intermediate semiconductor device, such as the arrangements shown in FIGS. 2 and 3. In addition, the walls of a crack assist structure may not remain fully intact during dicing, resulting in further changes to the appearance, structure, and number of walls 510. For example, blade dicing generally removes more material from a wafer than stealth dicing, so a blade diced die can have a fewer number of walls along the periphery relative to stealth dicing the same die. Thus, although FIG. 5 depicts two walls at each corner of the semiconductor device 500, different numbers of walls may be present. In another example, at least some of the walls 510 may appear cropped or fragmented as a result of dicing.

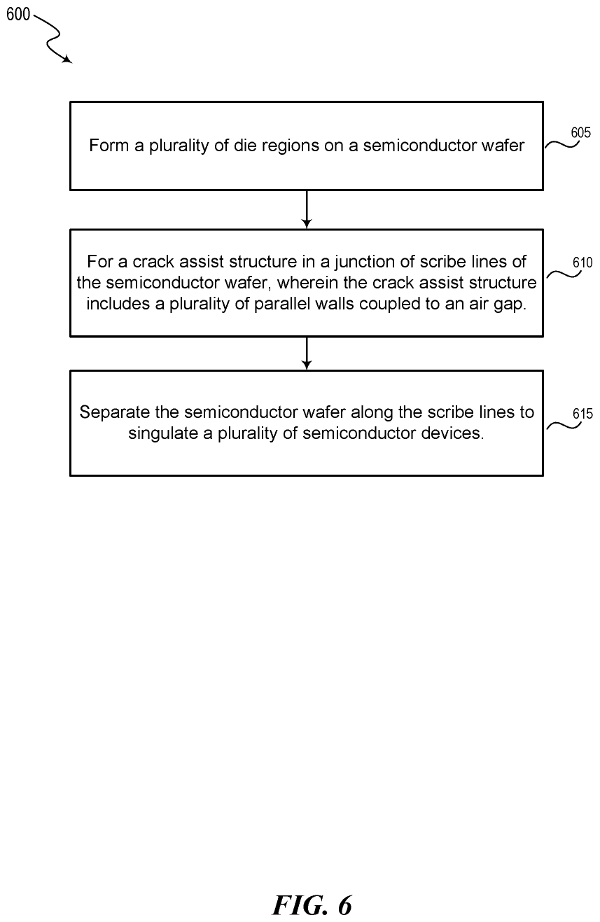

FIG. 6 is a flow chart illustrating a method 600 of fabricating a semiconductor device in accordance with an embodiment of the present disclosure. At 605, a plurality of die regions is formed on a semiconductor wafer. For example, this can include various patterning, etching, deposition, and other steps that produce integrated circuitry on the wafer in the plurality of die regions. In some embodiments, the semiconductor wafer can be a 45-degree silicon wafer.

At 610, a crack assist structure is formed in a junction of scribe lines of the semiconductor wafer. For example, the crack assist structure can be formed by forming an arrangement of parallel walls which extend vertically into a depth of the semiconductor wafer. In some embodiments, the arrangements of the parallel walls can be similar to crack assist structures 110, 310, and 410 of FIG. 4. The parallel walls can each coupled to an air gap, similar to the walls 212 of FIG. 2. Each air gap can be configured to redirect or guide cracks along the parallel walls.

At 615, the semiconductor wafer is separated along the scribe lines to singulate a plurality of semiconductor devices. In some embodiments, separating the semiconductor wafer can include stealth dicing the semiconductor wafer along the scribe lines. In some embodiments, the wafer can be thinned by grinding the backside prior to dicing. Other dicing methods can also be used, such as blade dicing or scribing and breaking. After singulation, the resulting dies can include one or more walls along a perimeter of the die that were previously part of the crack assist structure formed at 610. For example, the singulated die can be similar to semiconductor device 500 shown in FIG. 5. In some embodiments, a seal ring can be formed around a perimeter of each of the plurality of die regions. The seal ring can include a metal wall coupled to a second air gap and can be formed using the same process used to form the walls of the crack assist structure formed at 610. Thus in some embodiments, the seal ring can be formed at the same time as the walls of the crack assist structure at 610.

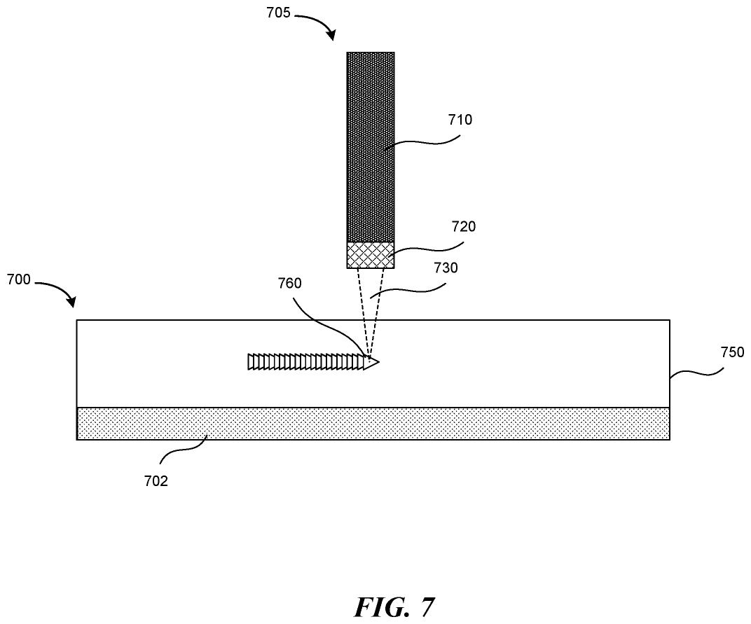

FIG. 7 is a cross-sectional view of semiconductor device assembly 700 undergoing stealth dicing. The semiconductor device assembly 700 can include a silicon layer 750 and an active layer 702. The active layer 702 can include one or more semiconductor devices spaced by scribe lines. The active layer 702 can also include one or more crack assist structures, such as those shown in FIGS. 1-4. The laser 705 includes a laser source 710 and laser optics 720. The laser source 710 passes a light beam through laser optics 720 to focus on an area within the silicon layer 750. The focused laser beam 730 can be adjusted by laser optics 720, displacing the irradiated location in the silicon layer 750.

The laser source 710 generates a high energy laser beam capable of cleaving the silicon lattice to create fracture region 760. The laser source can generate a laser beam having a wavelength between 1000 nm and 1400 nm. In some embodiments, the laser source generates a laser beam having a wavelength of 1342 nm.

Focused laser beam 730 has the ability to focus at a particular depth in silicon layer 750. The laser 705 can utilize multiphoton absorption in order to form a modified region within the silicon layer 750. A material becomes optically transparent if its absorption bandgap E is greater than a photon energy hv. The condition under which absorption occurs in the material is hv>E. However, the material yields absorption under the condition of nhv>E where n=2, 3, 4 even when the material is optically transparent for very high intensity lasers, hence the term multiphoton absorption.

Focused laser beam 730 can emit pulse waves. In the case of pulse waves, the intensity of laser light is determined by the peak power density (W/cm) of laser light at a light-converging point thereof. The multiphoton absorption occurs, for example, at a peak power density (W/cm) of 1×10 (W/cm) or higher. The peak power density is determined by (energy per pulse of laser light at the light-converging point)/(laser light beam spot cross-sectional area x pulse width). In the case of a continuous wave, the intensity of laser light is determined by the electric field strength (W/cm) of laser light at the light-converging point.

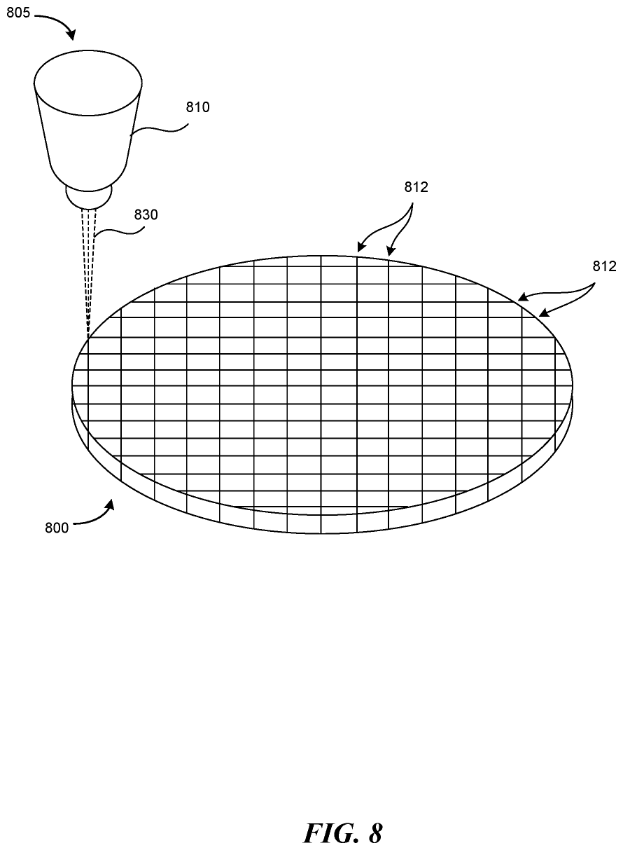

FIG. 8 shows a laser 805 performing stealth dicing on a semiconductor wafer 800. The laser 805 can include a laser source 810 that produces a focused laser beam 830, similar to laser 705 of FIG. 7. The semiconductor wafer 800 is shown with a silicon substrate layer facing up. The semiconductor wafer 800 can include a plurality of semiconductor dies separated by scribe lines corresponding to the grid pattern 812. The silicon lattice is cleaved by the laser 805 along grid pattern 812 to introduce fracture regions. Stress is then applied to separate the semiconductor wafer 800 into individual semiconductor devices or dies along the fracture regions. In some embodiments, the wafer is grinded to thin the silicon substrate layer after the stealth dicing step and before separation.

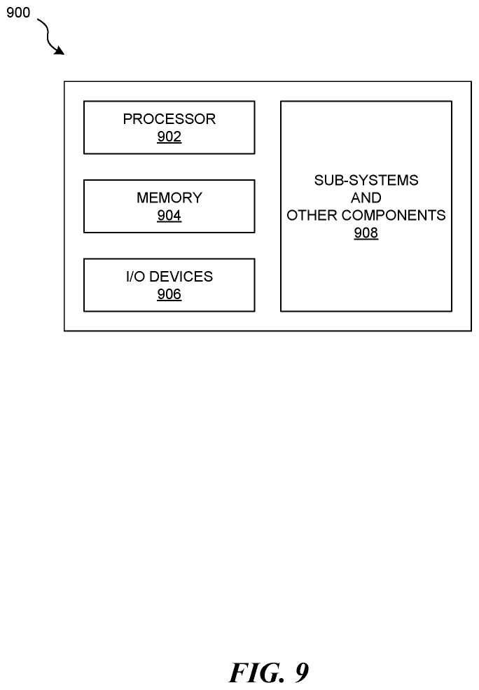

Any one of the semiconductor devices and/or dies having the features described above with reference to FIGS. 1-8 can be incorporated into any of a myriad of larger and/or more complex systems, a representative example of which is system 900 shown schematically in FIG. 9. The system 900 can include a processor 902, a memory 904 (e.g., SRAM, DRAM, flash, and/or other memory devices), input/output devices 906, and/or other subsystems or components 908. The semiconductor dies and/or packages described above with reference to FIGS. 1-8 can be included in any of the elements shown in FIG. 9. The resulting system 900 can be configured to perform any of a wide variety of suitable computing, processing, storage, sensing, imaging, and/or other functions. Accordingly, representative examples of the system 900 include, without limitation, computers and/or other data processors, such as desktop computers, laptop computers, Internet appliances, hand-held devices (e.g., palm-top computers, wearable computers, cellular or mobile phones, personal digital assistants, music players, etc.), tablets, multi-processor systems, processor-based or programmable consumer electronics, network computers, and minicomputers. Additional representative examples of the system 900 include lights, cameras, vehicles, etc. With regard to these and other examples, the system 900 can be housed in a single unit or distributed over multiple interconnected units (e.g., through a communication network). The components of the system 900 can accordingly include local and/or remote memory storage devices and any of a wide variety of suitable computer-readable media.

From the foregoing, it will be appreciated that specific embodiments of the invention have been described herein for purposes of illustration, but that various modifications may be made without deviating from the scope of the invention. Accordingly, the invention is not limited except as by the appended claims.

What is claimed:

1. A semiconductor device comprising:
a die region including circuitry;
a plurality of sidewalls defining outer edges of the semiconductor device; and
a scribe line region between the sidewalls and the die region, the scribe line region including a plurality of vertical walls extending at least partially through a thickness of the semiconductor device, each of the plurality of vertical walls including at least a portion extending substantially parallel to one of the plurality of sidewalls.

2. The semiconductor device of claim 1,
wherein each of the plurality of vertical walls extends vertically into an active layer of the semiconductor device and is coupled to a corresponding weak interface region configured to guide a crack along the vertical walls.

3. The semiconductor device of claim 2, wherein the weak interface region comprises an air gap.

4. The semiconductor device of claim 1, further comprising:
a seal ring surrounding the die region,
wherein the plurality of vertical walls comprises a same material as the seal ring.

5. The semiconductor device of claim 1, wherein each of the plurality of vertical walls comprises tungsten.

6. The semiconductor device of claim 1, wherein each of the plurality of vertical walls includes a chamfered corner.

7. The semiconductor device of claim 1, wherein the plurality of vertical walls includes a first vertical wall having a first width and a second vertical wall having a second width positioned between the first vertical wall and the die region, the first width being different than the second width.

8. The semiconductor device of claim 1, wherein the portion extending substantially parallel to one of the plurality of sidewalls is a first portion, and each of the plurality of vertical walls further includes a second portion extending at an oblique angle relative to the first portion.

9. The semiconductor device of claim 8, wherein the oblique angle is about 45 degrees.

10. The semiconductor device of claim 1, wherein the semiconductor device is a memory device formed on a 45-degree silicon substrate.

11. An intermediate semiconductor device comprising:
a plurality of die areas, each die area including a plurality of integrated circuits;
a scribe junction between proximate ones of the plurality of die areas, the scribe junction including a first scribe line having a first direction and a second scribe line having a second direction; and
a crack assist structure positioned at the scribe junction, the crack assist structure including:
a plurality of vertical walls extending at least partially through a thickness of the intermediate semiconductor device, wherein the plurality of walls includes a first wall running along the first direction in the first scribe line and a second wall running along the second direction in the second scribe line, and
a plurality of weak interface regions coupled to the plurality of vertical walls configured to guide a crack along the plurality of vertical walls.

12. The intermediate semiconductor device of claim 11, wherein the first direction and the second direction are orthogonal.

13. The intermediate semiconductor device of claim 11, wherein at least a subset of the plurality of vertical walls comprises:
a first portion running in the first direction;
a second portion running in the second direction;
and a third portion joining the first and second portions to form a chamfered corner.

14. The intermediate semiconductor device of claim 11, wherein at least a subset of the plurality of vertical walls comprises:
a first portion running in the first direction or the second direction; and
a second portion running in a third direction at an angle 45 degrees relative to the first portion.

15. The intermediate semiconductor device of claim 11, wherein a first vertical wall having a first width is positioned closer to a nearest die area than a second vertical wall having a second width, and wherein the first width is different than the second width.

16. The intermediate semiconductor device of claim 15, wherein the first width is greater than the second width.

17. The intermediate semiconductor device of claim 11, wherein the weak interface regions comprise one or more air gaps.

18. A method of fabricating a semiconductor device, the method comprising:
forming a plurality of die regions on a semiconductor wafer;
forming a crack assist structure in a junction of scribe lines of the semiconductor wafer, the crack assist structure including:
a plurality of parallel walls each coupled to an air gap, the air gap configured to guide cracks along the parallel walls; and
separating the semiconductor wafer along the scribe lines to singulate a plurality of semiconductor devices.

19. The method of claim 18, wherein separating the semiconductor wafer includes stealth dicing the semiconductor wafer along the scribe lines.

20. The method of claim 18, further comprising:
forming a seal ring around a perimeter of each of the plurality of die regions, the seal ring including a metal wall coupled to a second air gap.
